(19) United States
(12) Patent Application Publication
(10) Pub. No.: US 2014/0188414 A1
(43) Pub. Date: Jul. 3, 2014

(54) METHOD AND SYSTEM FOR MEASURING IMPEDANCE FOR DIAGNOSIS OF FUEL CELL STACK

(71) Applicants: KANGNAM UNIVERSITY INDUSTRY-ACADEMIA COOPERATION FOUNDATION, Yongin-si (KR); HYUNDAI MOTOR COMPANY, Seoul (KR)

(72) Inventors: Kwi Seong JEONG, Yongin-si (KR); Sae-Hoon KIM, Yongin-si (KR); Young Hyun LEE, Yongin-si (KR)

(73) Assignees: KANGNAM UNIVERSITY INDUSTRY-ACADEMIA COOPERATION FOUNDATION, Yongin-si (KR); HYUNDAI MOTOR COMPANY, Seoul (KR)

(21) Appl. No.: 14/137,897

(22) Filed: Dec. 20, 2013

(30) Foreign Application Priority Data
Dec. 27, 2012 (KR) 10-2012-0155394

(51) Int. Cl. G01R 31/36

(52) U.S. Cl. CPC G01R 31/3606
USPC 702/63

(57) ABSTRACT

A method and system for measuring impedance of a fuel cell stack that can rapidly measure impedance of a plurality of frequencies of the fuel cell stack using a sine wave signal in which a different plurality of frequencies are synthesized as an impedance measurement input signal, for diagnosis of the state of a fuel cell stack includes: synthesizing a plurality of sine wave signals having different frequencies; applying the synthesized signal as an input signal for measuring to the fuel cell stack; measuring a current and a voltage of the fuel cell stack; transforming the measured current and voltage of the fuel cell stack with a predetermined method; and calculating impedance of the fuel cell stack of the different frequencies based on the current and voltage of the fuel cell stack that is transformed with the predetermined method.

### CROSS-REFERENCE TO RELATED APPLICATION

This application claims priority to and the benefit of Korean Patent Application No. 10-2012-0155394 filed in the Korean Intellectual Property Office on Dec. 27, 2012, the entire contents of which are incorporated herein by reference.

### BACKGROUND

(a) Field

The present disclosure relates to a method and system for measuring impedance for diagnosis of a fuel cell stack that can rapidly measure impedance of a plurality of frequencies of the fuel cell stack using a sine wave signal in which a different plurality of frequencies are synthesized as an impedance measurement input signal, for diagnosis of the fuel cell stack.

(b) Background

A fuel cell is an energy generation device that converts chemical energy of fuel to electrical energy by electrochemically reacting the fuel with an oxidant within a stack. Fuel cells differ from internal combustion engines, which generate energy by oxidizing fuel by combustion.

A fuel cell may be used to supply industrial, household, and vehicle driving power and to supply power to a small-sized electric/electronic product.

For example, as a power supply source for driving a vehicle, certain polymer electrolyte membrane fuel cells or a proton exchange membrane fuel cells (PEMFC) having the highest power density among fuel cells have been researched extensively. These fuel cells have a fast starting time and fast power conversion reaction time due to a low operation temperature.

Such a PEMFC includes a membrane electrode assembly (MEA) having a catalyst electrode layer in which an electrochemical reaction occurs. A catalyst electrode layer is attached on each side of a solid polymer electrolyte film through which hydrogen ions move. The PEMFC also includes a gas diffusion layer (GDL) that performs a function of uniformly distributing reaction gases and transferring generated electrical energy, a gasket, an engaging device for maintaining an appropriate engaging pressure and air-tightness of reaction gases and coolant, and a bipolar plate for moving reaction gases and coolant.

When assembling a fuel cell stack using such a unit cell configuration, a combination of a gas diffusion layer and an MEA is positioned at an innermost portion of a cell. The MEA has a pair of catalyst electrode layers, i.e., an anode and a cathode to which a catalyst is applied so that hydrogen and oxygen may react at both surfaces of a polymer electrolyte film. At an outer portion at which an anode and a cathode are positioned, a gas diffusion layer and a gasket are stacked.

At the outside of the gas diffusion layer, a reaction gas (hydrogen, which is fuel and oxygen or air, which is an oxidizing agent) is supplied, and a bipolar plate having a flow field through which coolant passes is positioned.

By forming such a configuration in a unit cell, after a plurality of unit cells are stacked, an end plate for supporting a current collector, an insulation plate, and stacking cells is coupled at an outermost portion, and by repeatedly stacking and engaging unit cells between the end plates, a fuel cell stack is formed.

In order to obtain a potential necessary for an actual vehicle, unit cells should be stacked by a necessary potential, and stack of unit cells is a fuel cell stack.

A typical potential generated in a unit cell is about 1.3V. Therefore, in order to generate power necessary for vehicle driving, a plurality of cells are stacked in series.

For example, in a fuel cell vehicle, cell voltage is used for determining stack performance, driving state, and failure. The cell voltage may also be used for various controls of a system such as a flux control of a reaction gas, and is representatively measured by connecting a bipolar plate to a cell voltage monitor by a connector and a leading wire.

A conventional cell voltage monitor (CVM) directly measures a voltage of entire cells or two cells within a stack, and a main controller or superordinate controller that collects voltages of entire cells performs an integration processing of measurement information and monitors a voltage drop appearing due to a result of failure rather than a cause of failure.

Such a CVM is used for measuring a battery. FIG. 1 is a circuit diagram illustrating a conventional CVM and illustrates an example of a CVM of a battery in which 32 cells are coupled in series.

Because the conventional CVM directly measures a cell voltage, the CVM has a merit that position measurement of a failure cell is available, but has a very complicated circuit configuration, and thus, the device is difficult to assemble and maintain, is expensive, and cannot determine a cause of failure of the stack.

Further, in another conventional device, electrochemical impedance spectroscopy (EIS) may be used for determining an electrode reaction or a characteristic of a complex in an electrochemical field, can obtain a property and determine a structure of the complex and synthetic information of a reaction though analysis of a system response. The conventional device may also be used as a convenient tool in a chemical field application or medical engineering and bionics field.

However, an EIS requires a long test time for an off line, cannot perform real time detection, is expensive, and is used only for a test of a unit cell.

U.S. Pat. No. 7,531,253 (“U.S. '253”) relates to a method of monitoring an operation state of a fuel cell stack, and suggests a method of applying a low frequency current [Iₜₑₛₜ(t)] or a voltage signal to the stack, measuring a current or voltage [V(t)] signal of the stack appearing at this time, and diagnosing a system with a harmonic wave component of the measured current or voltage signal and a size thereof.

U.S. '253 determines whether a cell voltage drops with a change to a non-linear state at a linear segment of a system characteristic curve V/I and determines whether a system has a defect by measuring entire stack signals.

A basic concept of U.S. '253 is to diagnose a state of a stack by measuring only a stack voltage and diagnoses a change of a stack voltage according to a change of a current through cell voltage drop of the stack by analyzing a frequency.

Here, as shown in FIG. 2, upon normal driving, stack voltage/current characteristics have a linear relationship. In an abnormal driving condition, stack voltage/current characteristics are changed to a non-linear relationship. That is, when non-linearity of a stack voltage is measured, it may be determined that a state of the stack is abnormal.

Diagnosis is performed by additionally applying a frequency response diagnosis current of a sine wave [Bsin(ωt)] form to the stack while driving a stack by connecting loads, and in this case, a current of the stack becomes the sum of a basic operation current and a sine wave current [current of stack=A+Bsin(ωt)].

However, because a conventional method may use one small AC current change as an input, the method has a problem that decomposition performance is low, and a method of improving decomposition performance is needed.

Further, according to a conventional method, in order to diagnose voltage/current characteristics and impedance characteristics of different several frequencies, diagnosis should be performed on a frequency basis.

The above information disclosed in this Background section is only for enhancement of understanding of the background of the disclosure.

### SUMMARY

The present disclosure provides a method and system for measuring impedance for diagnosis of a state of a fuel cell stack having advantages of rapidly measuring impedance of a plurality of frequencies of the fuel cell stack using a sine wave signal in which a different plurality of frequencies are synthesized as an input signal for measuring impedance, for diagnosis of the fuel cell stack.

An exemplary embodiment of the present disclosure provides a method of measuring impedance for diagnosing a state of a fuel cell stack including: synthesizing a plurality of sine wave signals each having a different frequency to obtain a synthesized signal; applying the synthesized signal as an input signal for measuring to the fuel cell stack; measuring a current and a voltage of the fuel cell stack; transforming the measured current and voltage of the fuel cell stack with a predetermined method; and calculating impedance of the fuel cell stack for each of the different frequencies based on the current and voltage of the fuel cell stack that is transformed with the predetermined method.

The synthesized signal at the synthesizing of a plurality of sine wave signals may be a current signal. That is, the plurality of sine wave signals may be plurality of sine wave current signals.

At the transforming of the measured current and voltage, the transformation may be Fourier transformation.

The synthesizing of a plurality of sine wave signals may include generating a current signal of each frequency area by performing Fourier transformation of the synthesized current signal.

The calculating of impedance of the fuel cell stack may include acquiring impedance of the fuel cell stack of each of the different frequencies by dividing each voltage of a fuel cell in which Fourier transformation is performed by a corresponding current.

Another embodiment of the present disclosure provides an impedance measurement system for diagnosing a state of a fuel cell stack including: a signal generator that generates a plurality of sine wave signals having different frequencies; a signal synthesizer configured to synthesize a plurality of sine wave signals each having a different frequency to obtain a synthesized signal and applies the synthesized signal to the fuel cell stack; a fuel cell stack current/voltage measurement device configured to measure a current and a voltage of the fuel cell stack by applying the synthesized signal to the fuel cell stack; a Fourier transformer configured to perform Fourier transformation of a signal that is synthesized in the signal synthesizer and the current and the voltage of the fuel cell stack that is measured in the fuel cell stack current/voltage measurement device; and an impedance calculator configured to calculate impedance of the fuel cell stack of the different frequencies based on a current and a voltage of the fuel cell stack that is transformed by the Fourier transformer.

As described above, according to an exemplary embodiment of the present disclosure, by forming an impedance measurement input signal for state diagnosis of a fuel cell stack into a sine wave signal in which a different plurality of frequencies are synthesized, impedance of a plurality of frequencies of the fuel cell stack can be rapidly measured.

That is, according to an exemplary embodiment of the present disclosure, impedances of a fuel cell stack of several frequencies can be quickly measured at one time, actual application can be easily performed due to fast impedance measurement, and a driving condition of a fuel cell stack and diagnosis of a state can be improved.

### BRIEF DESCRIPTION OF THE DRAWINGS

FIG. 1 is a circuit diagram of a conventional CVM of a fuel cell stack.

FIG. 2 is a diagram illustrating a cell state diagnosis of a conventional fuel cell stack.

FIG. 3 is a schematic diagram of an impedance measurement system of a fuel cell stack according to an exemplary embodiment of the present disclosure.

FIG. 4 is a flowchart illustrating a method of measuring impedance of a fuel cell stack according to an exemplary embodiment of the present disclosure.

FIGS. 5 and 6 are graphs illustrating operation of a fuel cell stack according to an exemplary embodiment of the present disclosure.

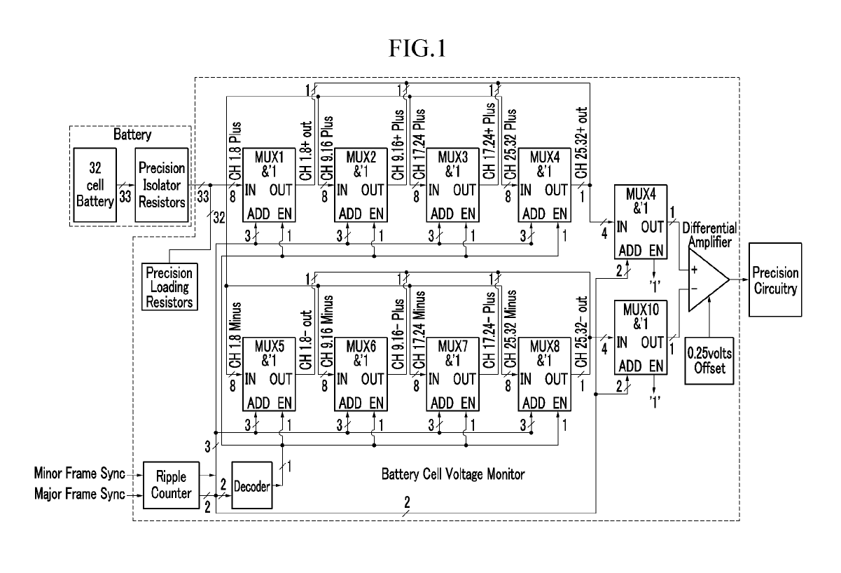

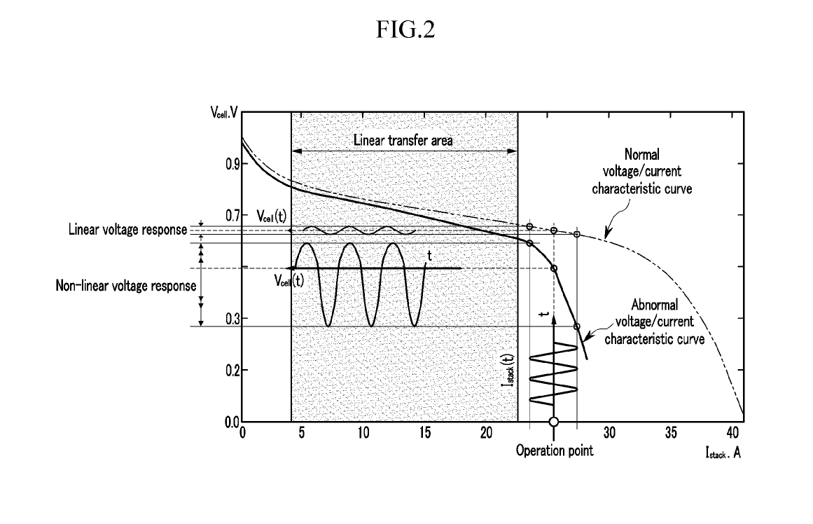

### DETAILED DESCRIPTION

The present disclosure will be described more fully hereinafter with reference to the accompanying drawings, in which exemplary embodiments of the disclosure are shown. The described embodiments may be modified in various different ways, all without departing from the spirit or scope of the present disclosure.

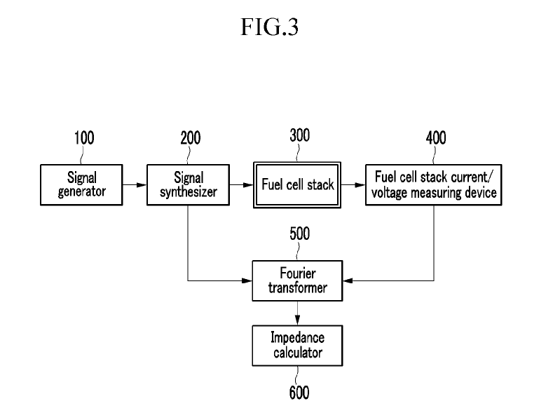

FIG. 3 is a schematic diagram of an impedance measurement system of a fuel cell stack according to an exemplary embodiment of the present disclosure.

An impedance measurement system of a fuel cell stack according to an exemplary embodiment of the present disclosure is a system that rapidly measures impedance of each of a plurality of frequencies of the fuel cell stack using a signal in which a different plurality of frequencies are synthesized as an input signal for measuring impedance for diagnosis of the fuel cell stack.

The impedance measurement system of the fuel cell stack according to an exemplary embodiment of the present disclosure may include a signal generator 100 that generates a plurality of sine wave signals having different frequency; a signal synthesizer 200 that syntheses a plurality of sine wave signals having different frequencies to obtain a synthesized signal, and to apply the synthesized signal to a fuel cell stack 300; a fuel cell stack current/voltage measuring device 400 that measures a current and a voltage of the fuel cell stack 300 by applying the synthesized signal to the fuel cell stack 300; a Fourier transformer 500 that performs Fourier transformation of a signal that is synthesized in the signal synthesizer 200 and/or a current and a voltage of the fuel cell stack 300 that is measured in the fuel cell stack current/voltage measuring device 400; and an impedance calculator 600 that calculates impedance of the fuel cell stack 300 of each of different frequencies based on a current and a voltage of the fuel cell stack 300 that is transformed by the Fourier transformer 500.

The signal generator 100, the signal synthesizer 200, the fuel cell stack current/voltage measuring device 400, the Fourier transformer 500, and the impedance calculator 600 may be at least one microprocessor operating by a predetermined program or hardware including the microprocessor, and the predetermined program may be formed with a series of commands for performing a method of measuring impedance of a fuel cell stack according to an exemplary embodiment of the present disclosure to be described later.

The signal generator 100, the signal synthesizer 200, the fuel cell stack current/voltage measuring device 400, the Fourier transformer 500, and the impedance calculator 600 may be formed in a synthesized body.

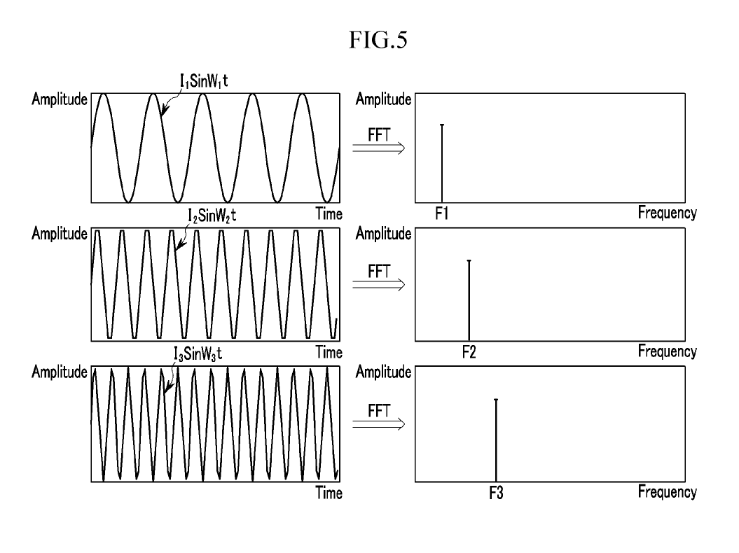

In an exemplary embodiment of the present disclosure, the signal generator 100 may generate, for example, a plurality of sine wave current signals I₁sinω₁t, I₂sinω₂t, . . . , Iₙsinωₙt having different frequencies f, as shown in FIG. 5.

In the plurality of sine wave current signals, I indicates a magnitude of a current, ω indicates 2πf as an angular frequency, f indicates a frequency, and n indicates the natural number.

In the plurality of sine wave current signals, I₁, I₂, . . . , Iₙ may be the same.

In an exemplary embodiment of the present disclosure, the signal generator 100 may generate, for example, sine wave current signals of 1 hz, 10 hz, and 1 khz.

The signal synthesizer 200 may generate a synthesized current signal Iᵢₙ(t) by synthesizing a plurality of sine wave current signals that are generated in the signal generator 100.

Iᵢₙ(t)=ΣIᵢ(t)=I sin ω₁t+I sin ω₂t+ . . . +I sin ωₙt

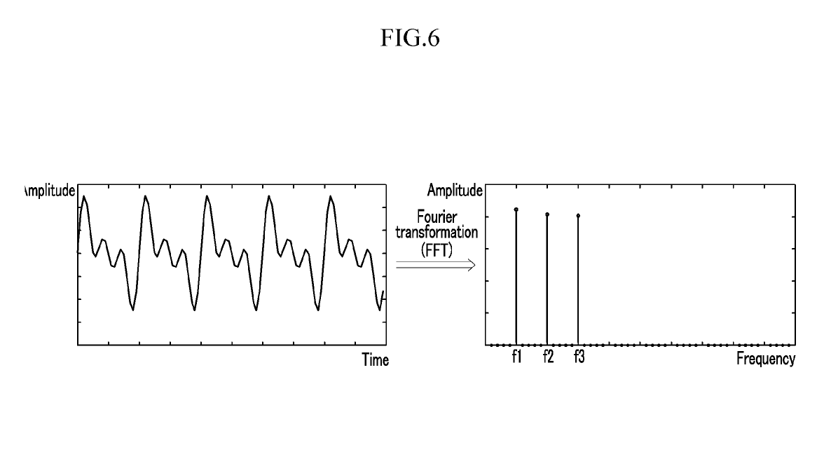

A synthesized current signal that is synthesized in the signal synthesizer 200 may have a form that is shown in FIG. 6. The synthesized current signal that is shown in FIG. 6 may be synthesized from three current signals that are shown in FIG. 5.

When a signal (e.g., current signal) that is synthesized in the signal synthesizer 200 is applied to the fuel cell stack 300, the fuel cell stack current/voltage measuring device 400 measures a current and a voltage of the fuel cell stack 300 through a general method.

The voltage for each corresponding current may be represented by V(ω), for example, (V(ω₁), V(ω₂), . . . , V(ωₙ).

The Fourier transformer 500 performs Fourier transformation of a signal of the signal synthesizer 200 and a current and a voltage that are measured by the fuel cell stack current/voltage measuring device 400 through a general method.

An example of signals (I(ω₁), I(ω₂), . . . , I(ωₙ)) (V(ω₁), V(ω₂), . . . , V(ωₙ)) in which Fourier transformation is performed by the Fourier transformer 500 is shown at the right side of a graph that is shown in FIGS. 5 and 6.

When Fourier transformation of a current and a voltage of the fuel cell stack 300 of a plurality of frequencies is performed by the Fourier transformer 500, the impedance calculator 600 calculates impedances (Z(ω₁), Z(ω₂), . . . , Z(ωₙ)) of each of corresponding frequencies by dividing voltages (V(ω₁), V(ω₂), . . . , V(ωₙ)) of a corresponding frequency in which Fourier transformation is performed by currents (I(ω₁), I(ω₂), . . . , I(wₙ)) of a corresponding frequency in which Fourier transformation is performed.

Z(ωᵢ)=V(ωᵢ)/I(ωᵢ); i=1, 2, . . . , n

Impedance of a corresponding frequency that is calculated by the impedance calculator 600 may be used for diagnosis of a state of the fuel cell stack.

Hereinafter, a method of measuring impedance of a fuel cell stack according to an exemplary embodiment of the present disclosure will be described in detail with reference to the attached drawings.

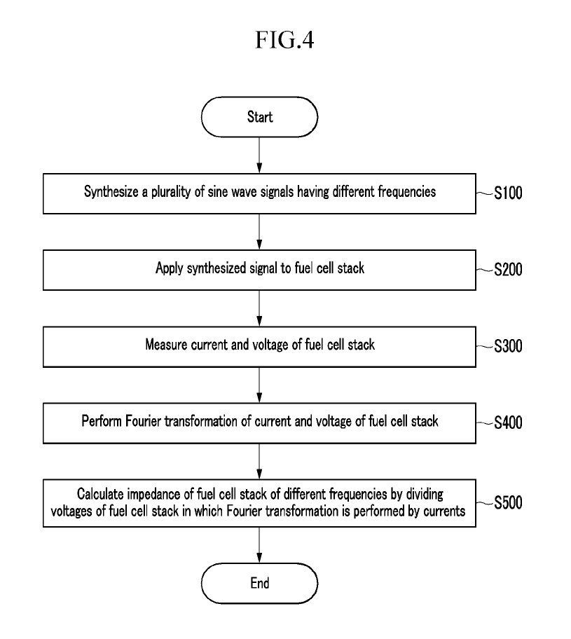

FIG. 4 is a flowchart illustrating a method of measuring impedance of a fuel cell stack according to an exemplary embodiment of the present disclosure.

As shown in FIG. 4, the signal synthesizer 200 synthesizes a plurality of sine wave signals (e.g., sine wave current signal) (Isinω₁t, Isinω₂t, . . . , Isinωₙt) having different frequencies that are generated by the signal generator 100 (S100).

The signal synthesizer 200 synthesizes the plurality of sine wave current signals and applies the synthesized current signal (I(t)=ΣIᵢ(t)=Isinω₁t+Isinω₂t+ . . . + Isinωₙt) as an impedance measurement input current signal to the fuel cell stack 300 (S200).

When the synthesized current signal is applied to the fuel cell stack 300 by the signal synthesizer 200, the fuel cell stack current/voltage measuring device 400 measures a current Iₒᵤₜ(t) and a voltage Vₒᵤₜ(t) of the fuel cell stack 300 (S300).

A current and a voltage of the fuel cell stack 300 that is measured by the fuel cell stack current/voltage measuring device 400 have a signal form in which different frequencies are synthesized.

When a current and a voltage of the fuel cell stack 300 are measured by the fuel cell stack current/voltage measuring device 400, the Fourier transformer 500 performs Fourier transformation of the measured current and voltage of the fuel cell stack 300, as shown on the right side graph of FIG. 6 (S400).

The Fourier transformer 500 performs Fourier transformation of a current signal that is synthesized in the signal synthesizer 200 and generates a current signal of each frequency area.

When Fourier transformation of a current and a voltage of the fuel cell stack 300 is performed by the Fourier transformer 500, the impedance calculator 600 calculates impedances (Z(ω₁), Z(ω₂), . . . , Z(ωₙ)) of a corresponding frequency by dividing voltages (V(ω₁), V(ω₂), . . . , V(ωₙ)) of a corresponding frequency in which Fourier transformation is performed by the Fourier transformer 500 by currents (I(ω₁), I(ω₂), . . . , I(ωₙ)) of a corresponding frequency in which Fourier transformation is performed (S500).

Each impedance of a corresponding frequency that is rapidly calculated by the impedance calculator 600 may be used for diagnosis of the fuel cell stack 300.

Thereby, according to an exemplary embodiment of the present disclosure, by forming an impedance measurement input signal for diagnosis of a fuel cell stack into a sine wave signal in which a plurality of different frequencies are synthesized, impedance of a plurality of frequencies of the fuel cell stack can be rapidly measured.

While this disclosure has been described in connection with what is presently considered to be practical exemplary embodiments, it is to be understood that the disclosure is not limited to the disclosed embodiments, but, on the contrary, is intended to cover various modifications and equivalent arrangements included within the spirit and scope of the appended claims.

### DESCRIPTION OF SYMBOLS

100: signal generator
200: signal synthesizer
300: fuel cell stack
400: fuel cell stack current/voltage measuring device
500: Fourier transformer
600: impedance calculator

What is claimed is:

1. A method of measuring impedance for diagnosing a state of a fuel cell stack, the method comprising:
synthesizing a plurality of sine wave signals, each having a different frequency to obtain a synthesized signal;
applying the synthesized signal as an input signal for measuring the fuel cell stack;
measuring a current and a voltage of the fuel cell stack;
transforming the measured current and voltage of the fuel cell stack with a predetermined method; and
calculating impedance of the fuel cell stack for each of the different frequencies based on the current and voltage of the fuel cell stack that is transformed with the predetermined method.

2. The method of claim 1, wherein the synthesized signal of the plurality of sine wave signals is a current signal.

3. The method of claim 2, wherein at the transforming of the measured current and voltage, the transformation is Fourier transformation.

4. The method of claim 3, wherein the synthesizing of a plurality of sine wave signals comprises generating a current signal of each frequency area by performing Fourier transformation of the synthesized current signal.

5. The method of claim 3, wherein the calculating of impedance of the fuel cell stack comprises acquiring impedance of the fuel cell stack of each of the different frequencies by dividing each voltage of a fuel cell in which Fourier transformation is performed by a corresponding current.

6. An impedance measurement system for diagnosing a state of a fuel cell stack, the impedance measurement system comprising:
a signal generator configured to generate a plurality of sine wave signals, each having a different frequency;
a signal synthesizer configured to synthesize the plurality of sine wave signals to obtain a synthesized signal and apply the synthesized signal to the fuel cell stack;
a fuel cell stack current/voltage measurement device configured to measure a current and a voltage of the fuel cell stack by applying the synthesized signal to the fuel cell stack;
a Fourier transformer configured to perform Fourier transformation of the synthesized signal and the current and the voltage of the fuel cell stack that is measured in the fuel cell stack current/voltage measurement device; and
an impedance calculator configured to calculate impedance of the fuel cell stack of each of the different frequencies based on the current and the voltage of the fuel cell stack that is transformed by the Fourier transformer.
